(19) United States
(12) Patent Application Publication
(10) Pub. No.: US 2024/0170341 A1
(43) Pub. Date: May 23, 2024

(54) SEMICONDUCTOR DEVICE AND METHOD OF MANUFACTURE

(71) Applicant: Taiwan Semiconductor Manufacturing Co., Ltd., Hsinchu (TW)

(72) Inventors: Yu-Ming Chen, Taipei (TW); Tsung-Lin Lee, Hsinchu City (TW); Chia-Ho Chu, Kaohsiung City (TW); Sung-En Lin, Xionglin Township (TW); Sen-Hong Syue, Zhubei City (TW)

(21) Appl. No.: 18/152,390

(22) Filed: Jan. 10, 2023

Related U.S. Application Data
(60) Provisional application No. 63/427,304, filed on Nov. 22, 2022.

(51) Int. Cl. H01L 21/8238; H01L 21/02; H01L 21/28; H01L 27/092; H01L 29/06; H01L 29/08; H01L 29/423; H01L 29/66; H01L 29/775

(52) U.S. Cl. CPC H01L 21/823857; H01L 21/02532; H01L 21/02603; H01L 21/28185; H01L 21/28194; H01L 21/823807; H01L 21/823814; H01L 27/092; H01L 29/0673; H01L 29/0847; H01L 29/42392; H01L 29/66439; H01L 29/66545; H01L 29/66553; H01L 29/775

(57) ABSTRACT

Semiconductor devices and methods of manufacture are discussed. In an embodiment, a method of manufacturing a semiconductor device includes: forming first nanostructures from a first material over a substrate; forming second nanostructures from a second material different from the first material over the substrate, wherein the first nanostructures and the second nanostructures alternate vertically above the substrate; removing the first nanostructures; after the removing the first nanostructures forming an interposer in between the second nanostructures; after the forming the interposer forming a first source/drain region over the substrate and in direct physical contact with the second nanostructures; and removing the interposer exposing surfaces of each of the second nanostructures.

### PRIORITY CLAIM AND CROSS-REFERENCE

This application claims the benefit of U.S. Provisional Application No. 63/427,304, entitled: “Semiconductor Device and Method of Manufacture,” filed on Nov. 22, 2022, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIG. 2 illustrates a cross-sectional view of a formation of a multi-layer stack over a substrate, in accordance with some embodiments.

FIG. 3 illustrates a cross-sectional view of a formation of nanostructures over a fin, in accordance with some embodiments.

FIG. 4 illustrates a cross-sectional view of a formation of an isolation region, in accordance with some embodiments.

FIGS. 5, 6A and 6B illustrates cross-sectional views of a formation of a dummy dielectric and a dummy gate, in accordance with some embodiments.

FIGS. 7A and 7B illustrates cross-sectional views of a formation of spacer layers, in accordance with some embodiments.

FIGS. 8A and 8B illustrates cross-sectional views of a formation of spacers, in accordance with some embodiments.

FIGS. 9A and 9B illustrates cross-sectional views of a formation of a recess through the multi-layer stack into the fin, in accordance with some embodiments.

FIGS. 10A and 10B illustrates cross-sectional views of a removal of a layer from the multi-layer stack, in accordance with some embodiments.

FIGS. 11A and 11B illustrates cross-sectional views of a formation of an interposer material, in accordance with some embodiments.

FIGS. 12A and 12B illustrates cross-sectional views of a formation of an interposer, in accordance with some embodiments.

FIGS. 13A, 13B, and 13C illustrates cross-sectional views of a formation of inner spacers, in accordance with some embodiments.

FIGS. 14A, 14B, 14C, and 14D illustrates cross-sectional views of a formation of a source/drain region in the recess, in accordance with some embodiments.

FIGS. 15A, 15B, and 15C illustrates cross-sectional views of a formation of a gate dielectric, in accordance with some embodiments.

FIGS. 16A and 16B illustrates cross-sectional views of a planarization process, in accordance with some embodiments.

FIGS. 17A and 17B illustrates cross-sectional views of an etching process on the gate dielectric, in accordance with some embodiments.

FIGS. 18A and 18B illustrates cross-sectional views of an etching process on the nanostructures, in accordance with some embodiments.

FIGS. 19A and 19B illustrates cross-sectional views of a formation of a gate dielectric layer and a gate electrode, in accordance with some embodiments.

FIGS. 20A, 20B, and 20C illustrates cross-sectional views of a formation of an interlayer dielectric over the gate electrode, in accordance with some embodiments.

FIGS. 21A, 21B, and 21C illustrates cross-sectional views of a formation of openings through the interlayer dielectric, in accordance with some embodiments.

FIGS. 22A, 22B, and 22C are cross-sectional views of a formation of contact plugs in the openings, in accordance with some embodiments.

FIGS. 23A, 23B, and 23C are cross-sectional views of a nano-FET, in accordance with some embodiments.

FIGS. 24A, 24B, and 24C are cross-sectional views of a nano-FET with additional conductive features, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described below in a particular context, namely a die comprising nano-FETs. Various embodiments may be applied, however, to dies comprising other types of transistors (e.g., fin field effect transistors (FinFETs), planar transistors, or the like) in combination with the nano-FETs. During manufacturing of nano-FET devices intermediate structures of the nano-FET devices undergo various thermal loop processes. During these various thermal loop processes nanosheets of the nano-FET devices are at risk of interface intermixing. This interface intermixing may lead to mobility degradation. By replacing layers of the nanosheets with a material less susceptible to intermixing the risk of nanosheet interface intermixing may be mitigated.

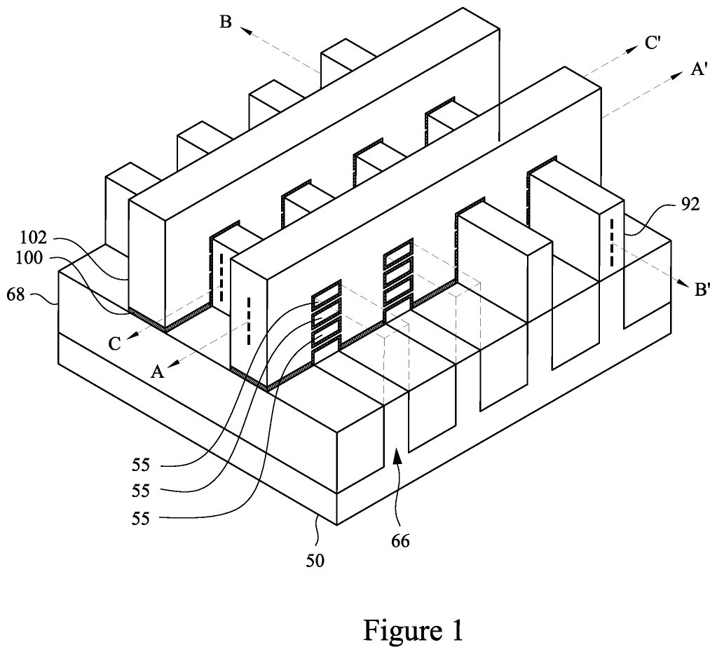

FIG. 1 illustrates an example of nano-FETs (e.g., nanowire FETs, nanosheet FETs, or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Cross-section A-A′ is along a longitudinal axis of a gate electrode 98 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

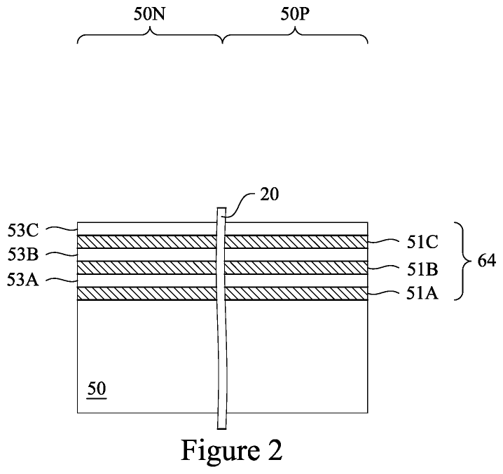

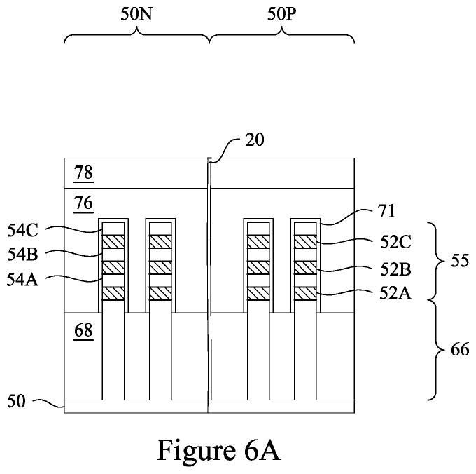

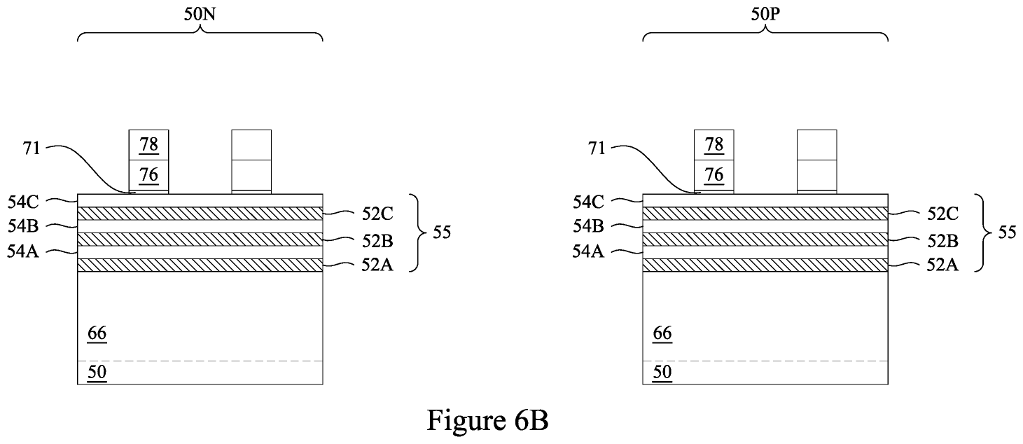

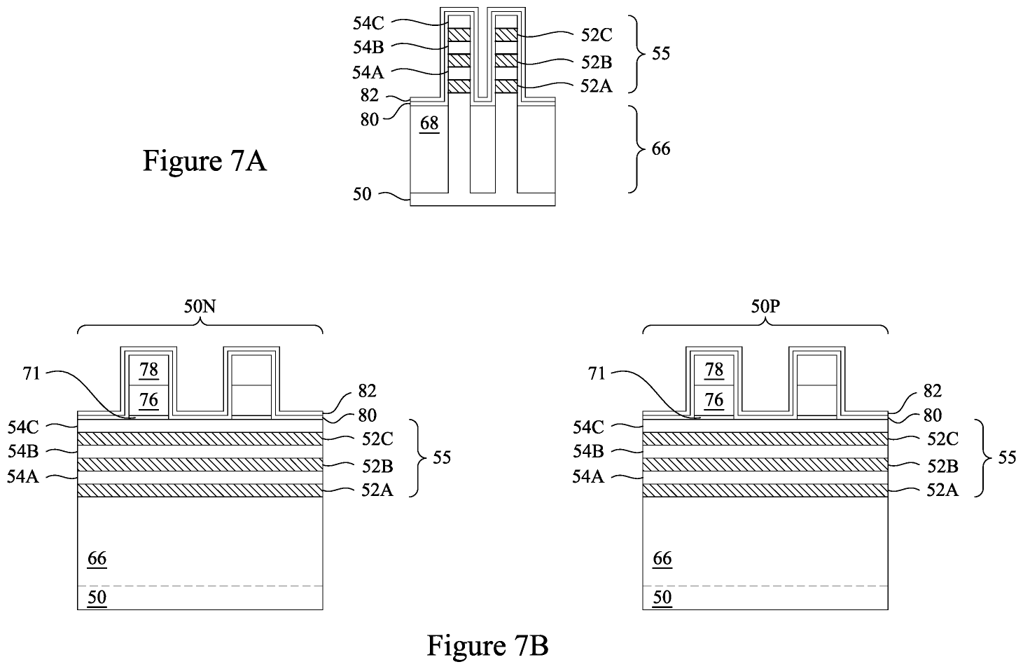

FIGS. 2 through 22C are cross-sectional views of intermediate stages in the manufacturing of nano-FETs, in accordance with some embodiments. FIGS. 2 through 5, 6A, 15A, 16A, 17A, 18A, 19A, 20A, 21A, 22A, and 23A illustrate reference cross-section A-A′ illustrated in FIG. 1. FIGS. 6B, 7B, 8B, 9B, 10B, 11B, 12B, 13B, 13C, 14B, 14D, 15B, 16B, 17B, 18B, 19B, 20B, 21B, 22B, and 23B illustrate reference cross-section B-B′ illustrated in FIG. 1. FIGS. 7A, 8A, 9A, 10A, 11A, 12A, 13A, 14A, 14C, 15C, 20C, 21C, 22C, and 23C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

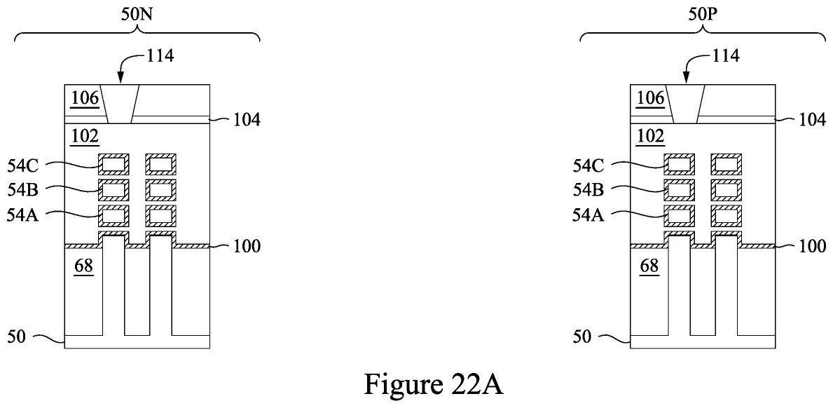

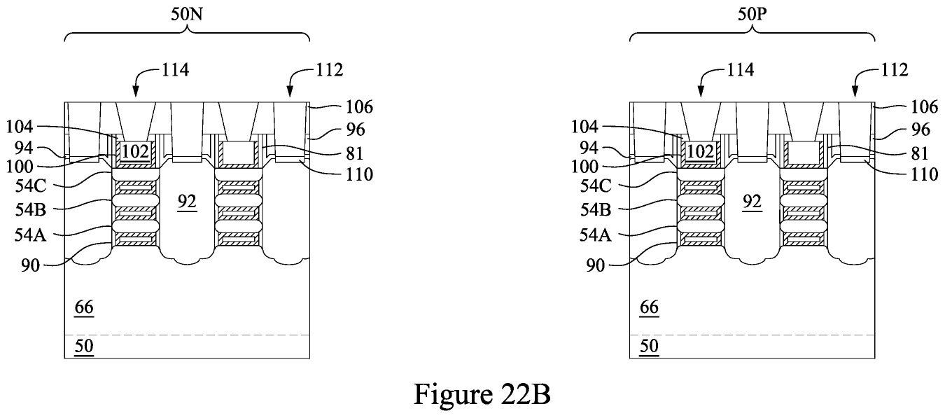

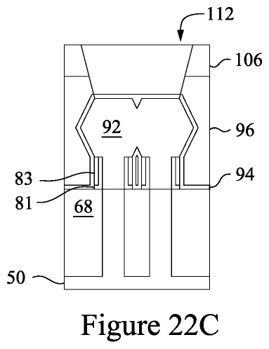

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 may be removed and the second semiconductor layers 53 may be patterned to form channel regions of nano-FETS in both the n-type region 50N and the p-type region 50P. In other embodiments, the second semiconductor layers 53 may be removed and the first semiconductor layers 51 may be patterned to form channel regions of nano-FETs in both the n-type region 50N and the p-type region 50P. In such embodiments, the channel regions in both the n-type region 50N and the p-type region 50P may have a same material composition (e.g., silicon, or another semiconductor material, such as silicon germanium) and may be formed simultaneously. FIGS. 22A, 22B, and 22C illustrate a structure resulting from such embodiments where the channel regions in both the p-type region 50P and the n-type region 50N comprise, for example, silicon.

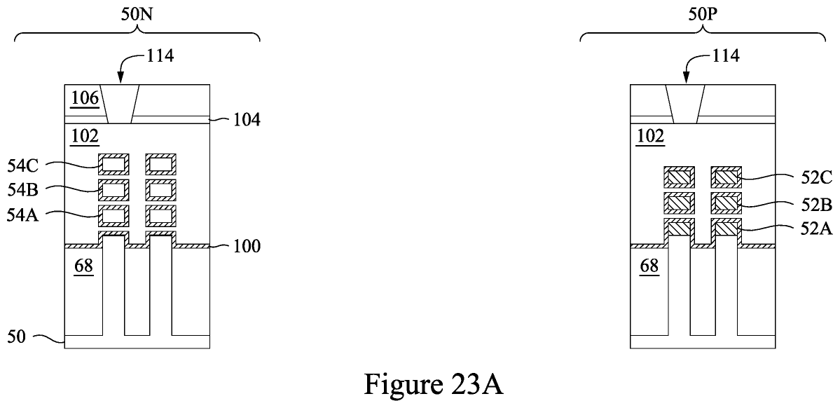

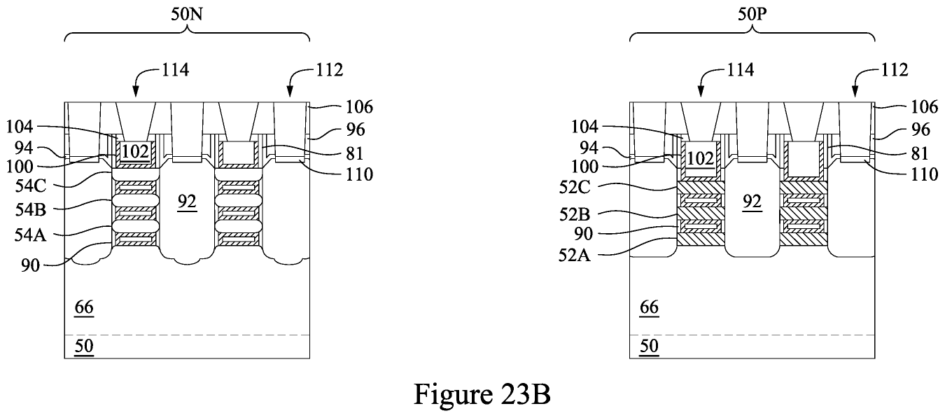

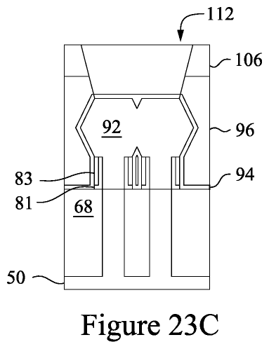

Nevertheless, in some embodiments the first semiconductor layers 51 may be removed and the second semiconductor layers 53 may be patterned to form channel regions of nano-FETs in either the n-type region 50N or the p-type region 50P, and the second semiconductor layers 53 may be removed and the first semiconductor layers 51 may be patterned to form channel regions of nano-FETs in either the p-type regions 50P or the n-type regions 50N. FIGS. 23A, 23B, and 23C illustrate a structure resulting from such embodiments where the channel regions in the p-type region 50P and the channel regions in n-type region 50N are formed from different layers from the multi-layer stack 64 comprising different materials, for example the channel regions in the p-type region 50P may comprise silicon germanium while the channel regions in the n-type region 50N may comprise silicon.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like.

The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material, thereby allowing the second semiconductor layers 53 to be patterned to form channel regions in either or both the n-type regions 50N and the p-type regions 50P. Similarly, the second semiconductor layers 53 of the second semiconductor material may be removed without significantly removing the first semiconductor layers 51 of the first semiconductor material, thereby allowing the first semiconductor layers 51 to be patterned to form channel regions in either or both the n-type regions 50N and the p-type regions 50P.

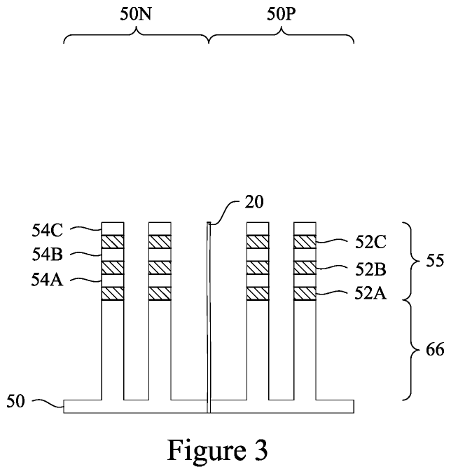

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-C (collectively referred to as the first nanostructures 52) from the first semiconductor layers 51 and define second nanostructures 54A-C (collectively referred to as the second nanostructures 54) from the second semiconductor layers 53. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66. In other embodiments, the channel regions in the n-type region 50N and the p-type region 50P may be formed simultaneously and have a same material composition, such as silicon, silicon germanium, or another semiconductor material. FIGS. 22A, 22B, and 22C illustrate a structure resulting from such embodiments where the channel regions in both the p-type region 50P and the n-type region 50N comprise silicon, for example.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

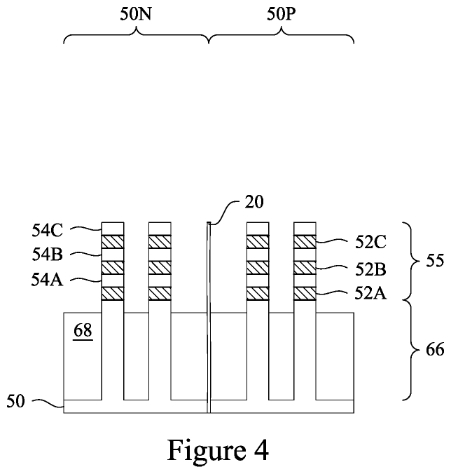

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

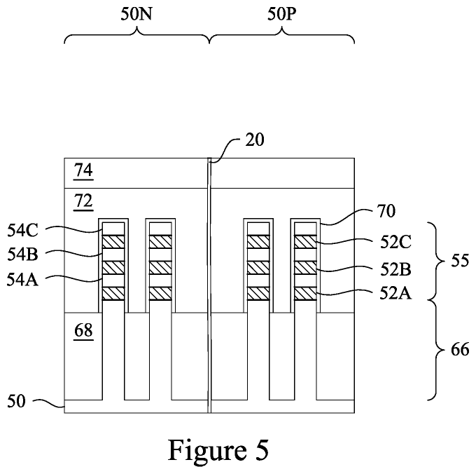

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a first mask layer 74 is formed over the dummy gate layer 72. The dummy gate layer 72 may be deposited over the dummy dielectric layer 70 and then planarized, such as by a CMP. The first mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The first mask layer 74 may include, for example, silicon nitride, silicon oxynitride, or the like. In this example, a single dummy gate layer 72 and a single first mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 20C illustrate various additional steps in the manufacturing of embodiment devices. FIGS. 6A, 7A, 8A, 9A, 10A, 11A, 12A, 13A, 14A, 14C, 15A, 15C, 16A, 17A, and 20C illustrate features in the n-type region 50N and the p-type region 50P. In FIGS. 6A and 6B, the first mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An anneal may be used to repair implant damage and to activate the implanted impurities.

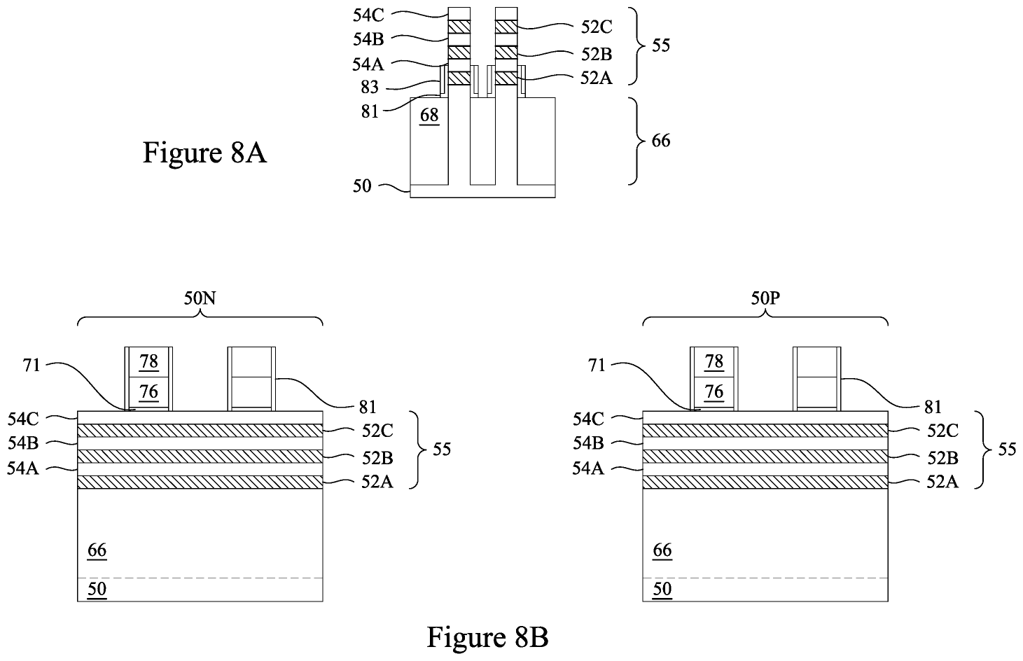

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy gate dielectrics 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

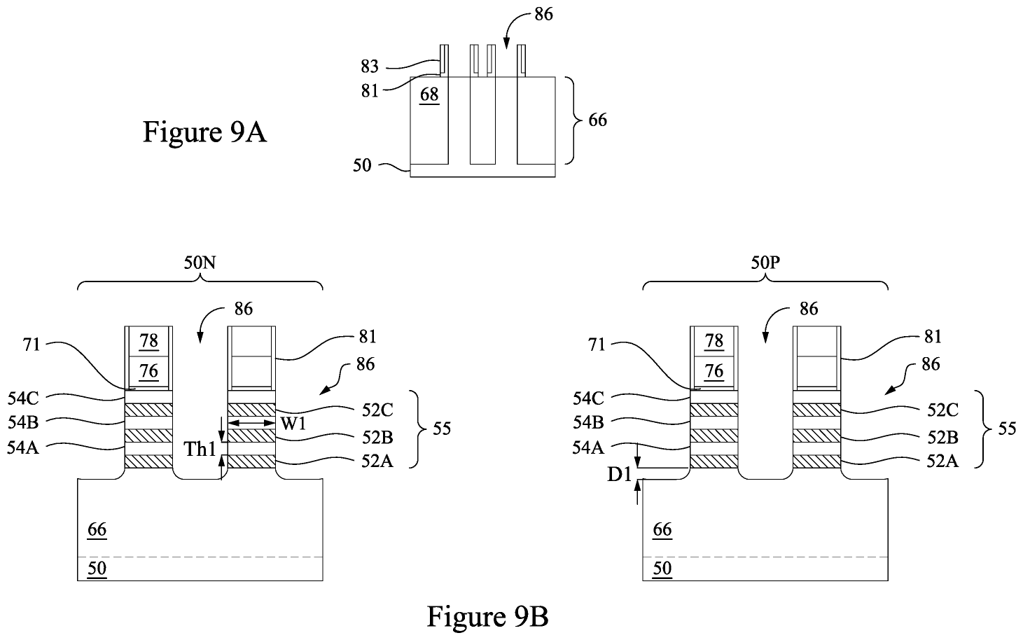

In FIGS. 9A and 9B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth. In an embodiment, the first recesses 86 is etched to a first depth D1 into the fins 66.

In an embodiment following the formation of the first recesses 86, the second nanostructures 54 have a first thickness Th1 and have a first width W1. In accordance with some embodiments, the first width W1 may be the same in both the n-type region 50N and the p-type region 50P. In other embodiments, the first width W1 may be different between the n-type region 50N and the p-type region 50P.

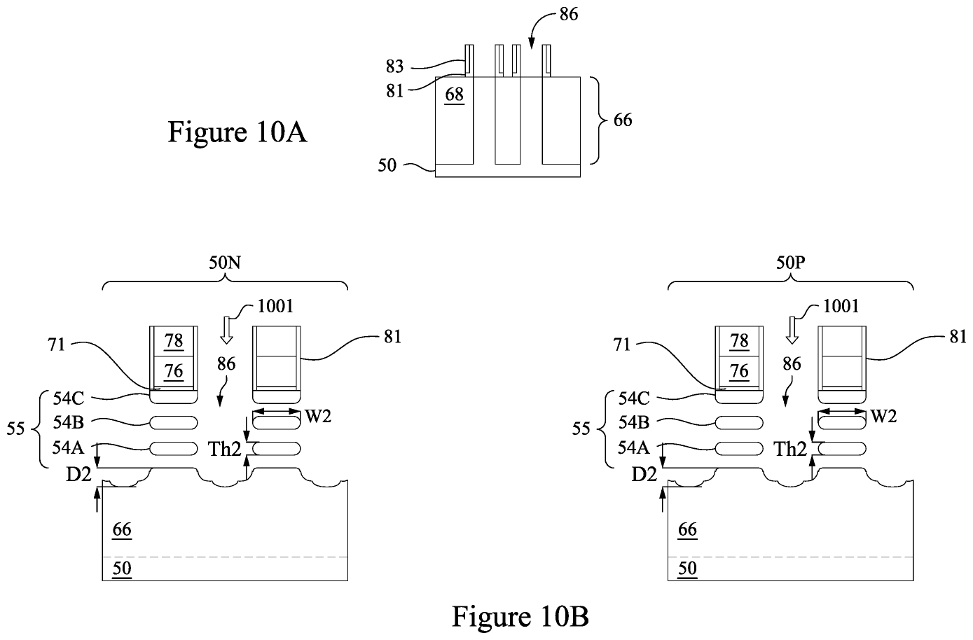

In FIGS. 10A and 10B, the first nanostructures 52 may be removed from both the n-type region 50N and the p-type region 50P by a first etching process 1001. The first etching process 1001 may be a dry etching process. The first etching process 1001 may utilize NF₃, Ar, He, the like, or a combination thereof. The first etching process 1001 may be carried out for a period of time in a range of 10 seconds to 120 seconds. The first etching process 1001 selectively removes the silicon germanium of the first nanostructures 52 in both the n-type region 50N and the p-type region 50P while leaving portions of the silicon of the second nanostructures 54 intact in both the n-type region 50N and the p-type region 50P. In an embodiment, the first etching process 1001 has a first etch rate (utilizing NH₃, Ar, He, the like, or a combination thereof) for silicon germanium and has a second etch rate for silicon. In an embodiment, the first etch rate may be different than the second etch rate. However, any suitable etching process and etching parameters may be utilized.

In this embodiment, following the first etching process 1001 the second nanostructures 54 in the n-type region 50N and the p-type region 50P may have a second thickness Th2 and a second width W2. In some embodiments, the second thickness Th2 of the second nanostructures 54 is less than the first thickness Th1 of the second nanostructures 54. In other embodiments, the second thickness Th2 of the second nanostructures 54 may be equal to the first thickness Th1 of the second nanostructures. In some embodiments, the second width W2 of the second nanostructures 54 is less than the first width W1 of the second nanostructures 54. In other embodiments, the second width W2 of the second nanostructures 54 may be equal to the first width W1 of the second nanostructures. Further, a first gap distance may exist between the fins 66 and the second nanostructure 54A in the n-type region 50N and in the p-type region 50P and between the individual second nanostructures 54 in the n-type region 50N and in the p-type region 50P.

In an embodiment, the fins 66 may also be formed from silicon. In this embodiment, following the first etching process 1001 the first recesses 86 in the n-type regions 50N and in the p-type regions 50P may be further etched to a second depth D2 into the fins 66, where the second depth extends further into the fins 66 than the first depth D1.

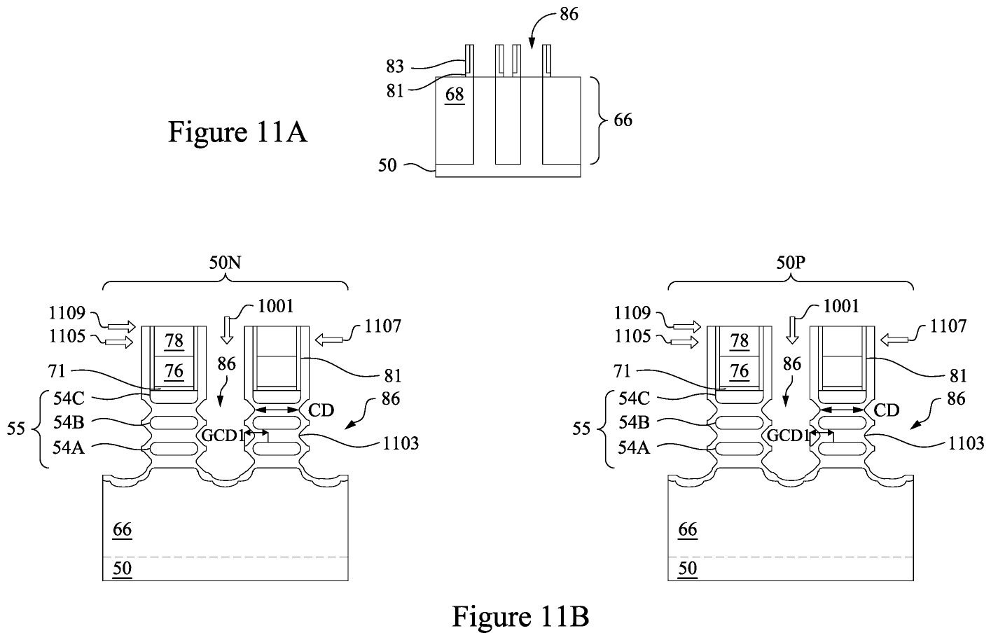

Optionally, following the removal of the first nanostructures 52 in the n-type region 50N and in the p-type region 50P, an oxide film (not separately illustrated) may be deposited or formed over exposed surfaces of the second nanostructures 54 in the n-type region 50N and in the p-type region 50P and exposed surfaces of the fins 66 in the n-type region 50N and in the p-type region 50P. The oxide film may be deposited or formed by such methods as atomic layer deposition, oxidation, or the like. However, any suitable deposition process may be used. The oxide film may help improve the gap-fill ability of a contour-flowable chemical vapor deposition (c-FCVD) process (as discussed in greater detail below with respect to FIGS. 11A and 11B).

In FIGS. 11A and 11B, a first deposition process 1101 is utilized to deposit an interposer material 1103 over the exposed surfaces of the fins 66 in the n-type region 50N and in the p-type region 50P, the exposed surfaces of the second nanostructures 54 in the n-type regions 50N and in the p-type region 50P and on sidewalls of the first spacers 81 in the n-type region 50N and in the p-type region 50P. In some embodiments, the interposer material 1103 is a seam-free interposer material (not separately illustrated). In an embodiment, the interposer material 1103 fills the first gap distance between the fins 66 and the second nanostructure 54A in the n-type region 50N and in the p-type region 50P and between the individual second nanostructures 54 in the n-type region 50N and in the p-type region 50P. Further, the interposer material 1103 may have lateral filling capability up to a sheet CD of 120 nm. In an embodiment the sheet CD may be equal to the third width W3.

In some embodiments, the first deposition process 1101 is a deposition process that can fill the regions between the second nanostructures 54, such as a c-FCVD process, used to deposit the interposer material 1103 utilizing various precursors and plasma sources, such as a first precursor, a second precursor, a third precursor, etc. The various precursors may be applied with the facilitation of a carrier gas or a diluent. Following the first deposition process 1101 (and any additional subsequent treatment processes discussed in greater detail later), the interposer material 1103 may comprise silicon oxide, silicon nitride, silicon oxynitride, the like, or a combination thereof.

In an embodiment, the first precursor may be a silicon-containing precursor utilized to provide silicon for the interposer material 1103. The silicon-containing precursor may be trisilylamine (TSA). However, any suitable silicon-containing precursor may be utilized.

In an embodiment, the second precursor may be a nitrogen-containing precursor utilized to provide nitrogen for the interposer material 1103. The nitrogen-containing precursor may be ammonia (NH₃). However, any suitable nitrogen-containing precursor may be utilized.

In an embodiment, the third precursor may be an oxygen-containing precursor utilized to provide oxygen for the interposer material 1103. The oxygen-containing precursor may be oxygen (O*) or the like. In some embodiments, the oxygen-containing precursor may be oxygen plasma formed from plasma precursors such as diatomic oxygen or ozone. However, any suitable oxygen-containing precursor may be utilized.

In an embodiment, the carrier gas or the diluent may be used to push or dilute one or more of the precursors. In an embodiment in which the carrier gas or diluent is utilized with the oxygen plasma, the carrier gas or diluent may also be a plasma such as argon (Ar*) or the like. However, any suitable carrier gas or diluent may be utilized.

In some embodiments where the interposer material 1103 comprises silicon nitride following the first deposition process 1101, the first deposition process 1101 may utilize the first precursor (e.g. the silicon-containing precursor) and the second precursor (e.g. the nitrogen-containing precursor) without the use of the third precursor (e.g. the oxygen-containing precursor) to provide the various precursors utilized in forming the silicon nitride. In this embodiment, an amount of the first precursor utilized may be controlled to be different than an amount of the second precursor utilized. By altering the amount of the first precursor utilized compared to the amount of the second precursor utilized a composition of the interposer material 1103 may be better controlled.

In other embodiments where the interposer material 1103 comprises silicon oxide following the first deposition process 1101, the first deposition process 1101 may utilize the first precursor (e.g. the silicon-containing precursor) and the third precursor (e.g. the oxygen-containing precursor) without the use of the second precursor (e.g. the nitrogen-containing precursor) to provide the various precursors utilized in forming the silicon oxide. In this embodiment, an amount of the first precursor utilized may be controlled to be different than an amount of the third precursor utilized. By altering the amount of the first precursor utilized compared to the amount of the third precursor utilized the composition of the interposer material 1103 may be better controlled.

In some embodiments where the interposer material 1103 comprises silicon oxynitride following the first deposition process 1101, the first deposition process 1101 may utilize the first precursor (e.g. the silicon-containing precursor), the second precursor (e.g. the nitrogen-containing precursor), and the third precursor (e.g. the oxygen-containing precursor) to provide the various precursors utilized in forming the silicon oxynitride. In this embodiment, an amount of the first precursor utilized, an amount of the second precursor utilized, and an amount of the third precursor utilized may be controlled so that an amount of each precursor utilized is different from each other. By altering the amount of each precursor utilized the composition of the interposer material 1103 may be better controlled.

A profile of the interposer material 1103 may be adjusted by tuning parameters of the first deposition process 1101, for example, the profile of the interposer material 1103 may be adjusted by tuning the various precursor flow rates and the ratios of the various precursors. Further, by adjusting a precursor ratio a contour profile and bottom-up buildup on the exposed surface of the fins 66 may be better controlled. For example, increasing the second precursor flow rate (e.g. a flow rate of the nitrogen-containing precursor) facilitates precursor cross-link and improved flowable characteristics of the interposer material 1103 allowing for improved lateral filling capability of the interposer material 1103 as well as improving the interposer material 1103 to have more uniform sidewall recesses. In an embodiment, the lateral filling capability of the interposer material 1103 is at least in part due to capillary action. The interposer material 1103, deposited by the first deposition process 1101 (e.g. the c-FCVD process), may have a capillarity that causes the interposer material 1103 to move laterally filling in gaps in between the second nanostructures 54. In some embodiments, the capillarity of the interposer material 1103 is such that the interposer material 1103 laterally fills in the gaps in between the second nanostructures so that the interposer material 1103 is a seam-free interposer material across the first gap distance. Additionally, in an embodiment, increasing the first precursor ratio has the effect of simulating characteristics of an atomic layer deposition (ALD) process. Increasing the first precursor achieves a greater contour profile and less bottom-up buildup of the interposer material 1103 along the exposed surfaces of the fins 66.

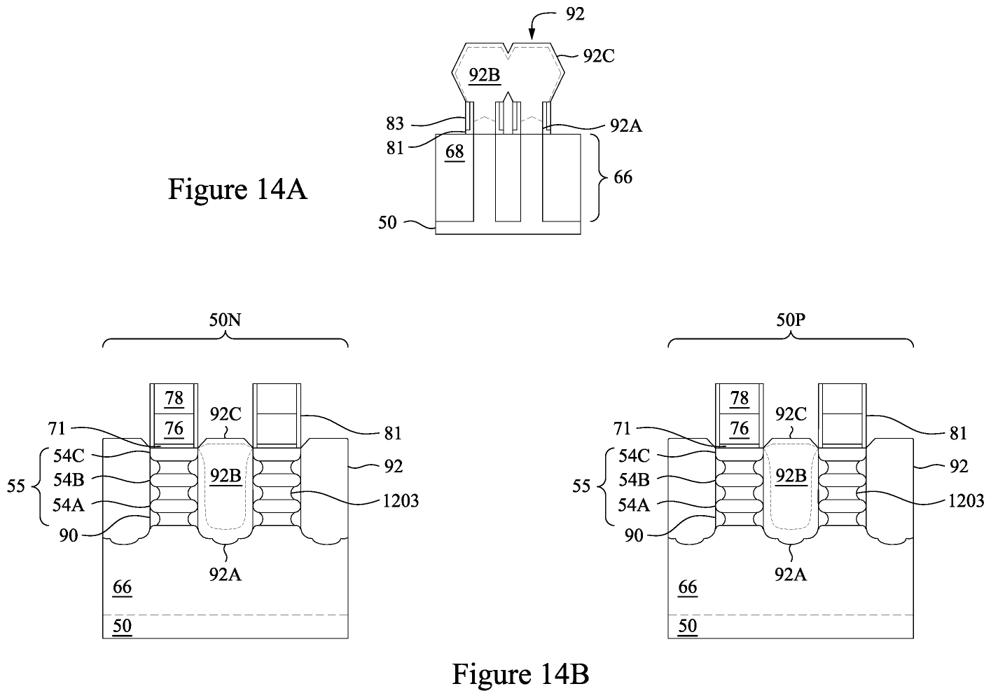

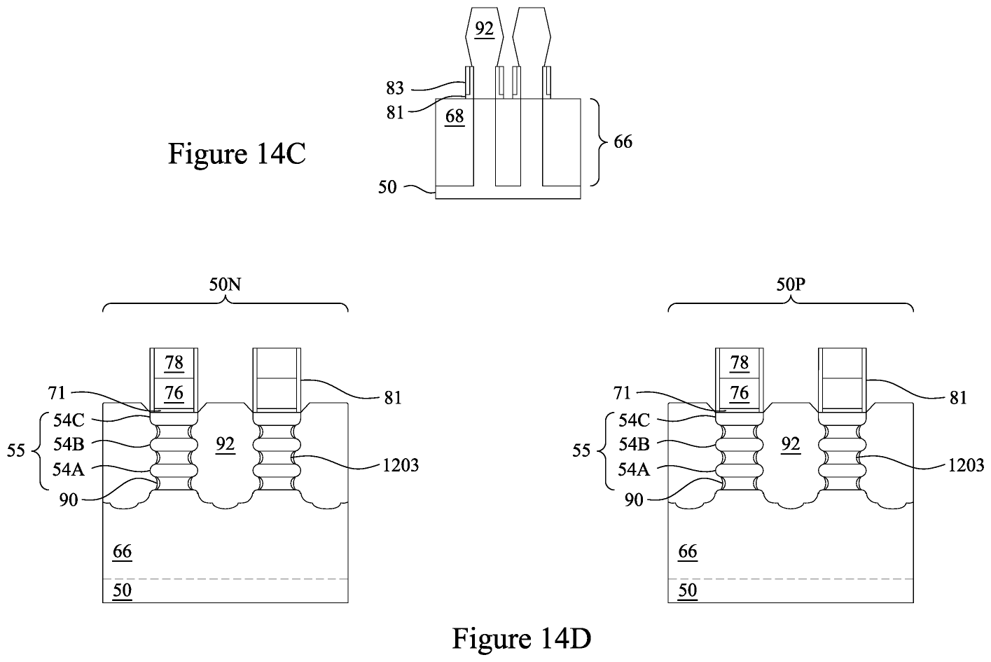

Further, in accordance with some embodiments, tuning the contour profile of the interposer material 1103, reducing the interposer material 1103 bottom up build up over the fins 66 and improving the uniform sidewall recesses of the interposer material 1103 in combination or individually by adjusting the various precursor amounts utilized, the various precursor flow rates, and the various precursor ratios forms a conformal deposition of the interposer material 1103 during the first deposition process 1101. The conformal deposition has the effect of improved facilitation of the epitaxial growth of the epitaxial source/drain regions 92 (discussed in greater detail with respect to FIGS. 14A through 14D).

Following the first deposition process 1101, the interposer material 1103 may optionally be subjected to a post-deposition curing 1105. In an embodiment, the post-deposition curing 1105 creates a densified film (not separately illustrated) in the interposer material 1103. The post-deposition curing 1105 may be carried out for a duration in a range of 10 seconds to 180 seconds. It has been observed that performing the post-deposition curing 1105 for less than 10 seconds may not be suitable for creating the densified film and performing the post-deposition curing 1105 for more than 180 seconds may not be suitable for creating the densified film. In some embodiments, the densified film has a greater density than the underlying interposer material 1103.

In some embodiments, the post-deposition curing 1105 may consist of an oxidation process which introduces oxygen to the exposed surfaces of the interposer material 1103. In a particular embodiment the oxidation process introduces oxygen (e.g. ozone (O₃)) to the interposer material 1103 so that the oxygen will diffuse into (and form a diffusion gradient) and react with the interposer material 1103 that had been previously deposited. As such, if the interposer material 1103 as deposited contained no oxygen (e.g., SiN), the post-deposition curing 1105 will add oxygen to at least a portion of the interposer material 1103 (e.g., to form SiON), while in embodiments which already comprise oxygen (e.g., SiON), the post-deposition curing 1105 will increase the concentration of oxygen adjacent to the exposed surfaces.

Additionally, in some embodiments the oxidation process is also performed with a curing process. In a particular embodiment the curing process may be an ultraviolet (UV) curing process to help facilitate forming the densified film. However, any suitable curing process such as a thermal curing process, the like or a combination thereof, may be utilized. In some embodiments, by introducing oxygen (e.g. ozone) to the interposer material 1103 and performing a UV curing process further densifies the densified film.

In accordance with some embodiments, the interposer material 1103 may be subjected to a post-deposition treatment 1107. In an embodiment the post-deposition treatment 1107 may further oxidize the densified film and help reduce the risk of steam penetration into the interposer material 1103 during a subsequent post-deposition anneal process 1109 (discussed in greater detail below). The post-deposition treatment 1107 may be a high-temperature sulfuric acid-hydrogen peroxide mixture (HTSPM) process or the like. In an embodiment where the post-deposition treatment 1107 is the HTSPM process, the HTSPM process may be performed utilizing a mixture of sulfuric acid (H₂SO₄) and hydrogen peroxide (H₂O₂). The HTSPM process may be carried out for a duration of time in a range of 30 seconds to 480 seconds. It has been observed that performing the HTSPM process for less than 30 seconds may not suitably oxidize the densified film and performing the HTSPM process for more than 480 seconds may not suitably oxidize the densified film.

Further, after the post-deposition treatment 1107 the interposer material 1103 may be subjected to a post-deposition anneal process 1109. In some embodiments the post-deposition anneal process 1109 may be a furnace anneal process. However, any suitable annealing process may be applied.

In some embodiments, the post-deposition anneal process 1109 may be directed at forming either a more oxide-like interposer or a more nitride-like interposer. In some embodiments directed at forming the more oxide-like interposer from the interposer material 1103, the furnace anneal process may facilitate film conversion and lead to a thermal oxide-like interposer (not separately illustrated). The furnace anneal process may utilize steam (e.g. vaporized H₂O) or oxygen gas. In this embodiment, the furnace anneal process may be carried out at a temperature in a range of 300° C. to 800° C. In some embodiments, the furnace anneal process utilizing steam or oxygen gas may be carried out at a temperature not to exceed 800° C. It has been observed that performing the furnace anneal process at a temperature less than 300° C. may not be suitable for film conversion and performing the furnace anneal process at a temperature greater than 800° C. may not be suitable for film conversion. In this embodiment, a concentration gradient of oxygen may be present at a surface of the interposer material 1103. In this embodiment, the concentration gradient of oxygen may have a first gradient concentration depth GCD1 into the surface of the interposer material 1103.

In other embodiments directed at forming the more nitride-like interposer from the interposer material 1103, the furnace anneal process further densifies the film leading to a nitride-like interposer. The furnace anneal process may utilize nitrogen gas or argon gas. The furnace anneal process may be carried out at a temperature in a range of 300° C. to 1000° C. It has been observed that performing the furnace anneal process at a temperature less than 300° C. may not suitably densify the film and performing the furnace anneal process at a temperature greater than 1000° C. may not suitably densify the film. In this embodiment, a concentration gradient of nitrogen may be present at the surface of the interposer material 1103. In this embodiment, the concentration gradient of nitrogen may have a first gradient concentration depth GCD1 into the surface of the interposer material 1103.

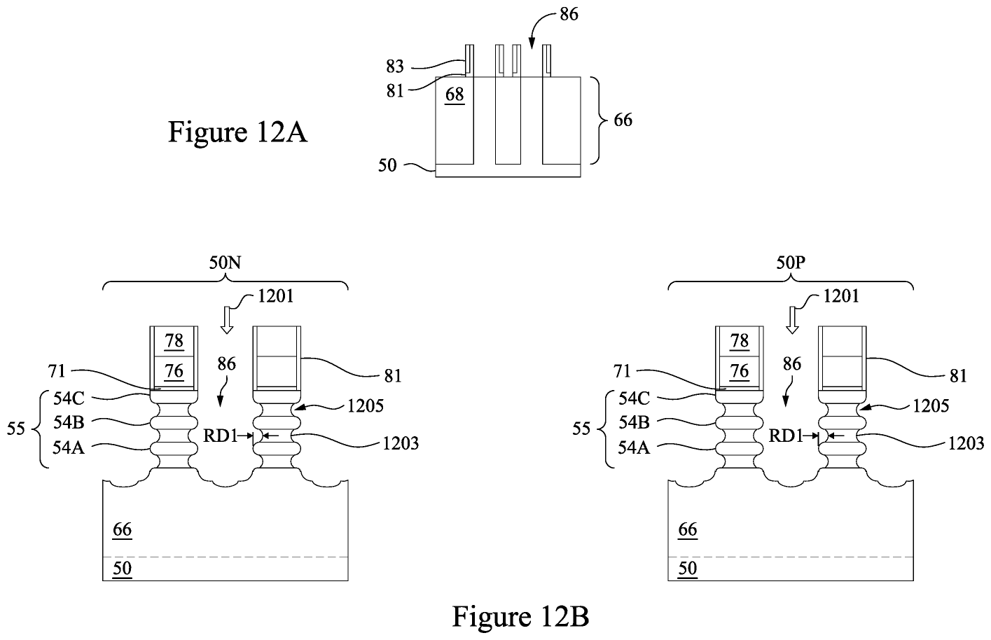

In FIGS. 12A and 12B, the interposer material 1103 is subjected to a second etching process 1201 forming the interposer 1203. In some embodiments the interposer 1203 is a seam-free interposer (not separately illustrated). The second etching process 1201 removes portions of the interposer material 1103 over the exposed surfaces of the fins 66 and from the sidewall recess of the interposer material 1103 forming interposer recesses 1205 in between the second nanostructures 54. The interposer recesses 1205 may have a first recess depth RD1. In some embodiments, the first recess depth RD1 is recessed into the interposer material 1103 to the first gradient concentration depth GCD1 in between the nanostructures 55.

In an embodiment, the second etching process 1201 may be a dry etching process. The dry etching process may utilize hydrogen fluoride (HF) gas, ammonia (NH₃) gas, the like, or a combination thereof. However, any suitable etching process or etching parameters may be utilized to form the interposer 1203.

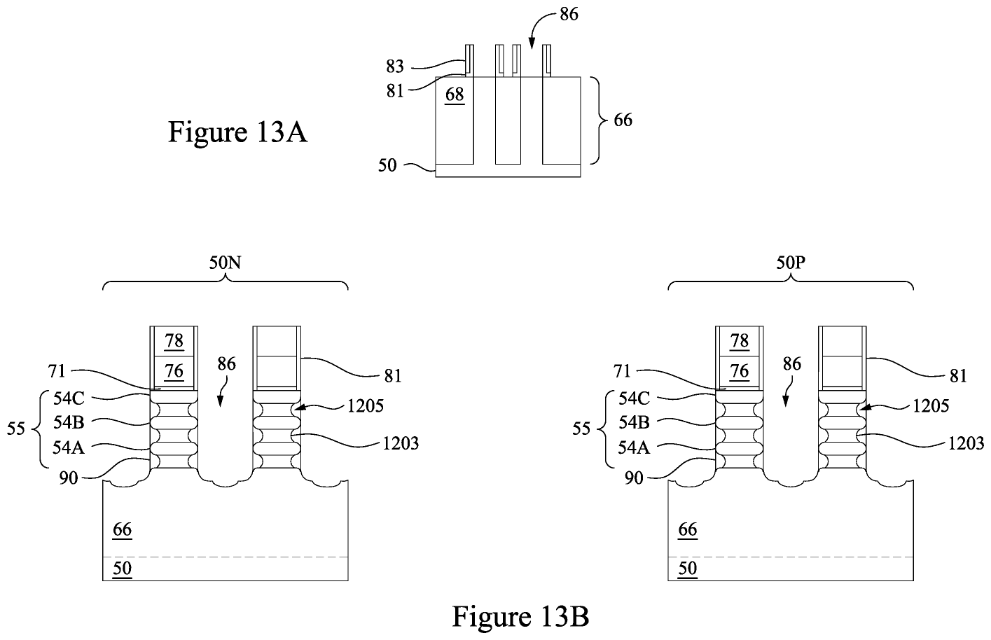

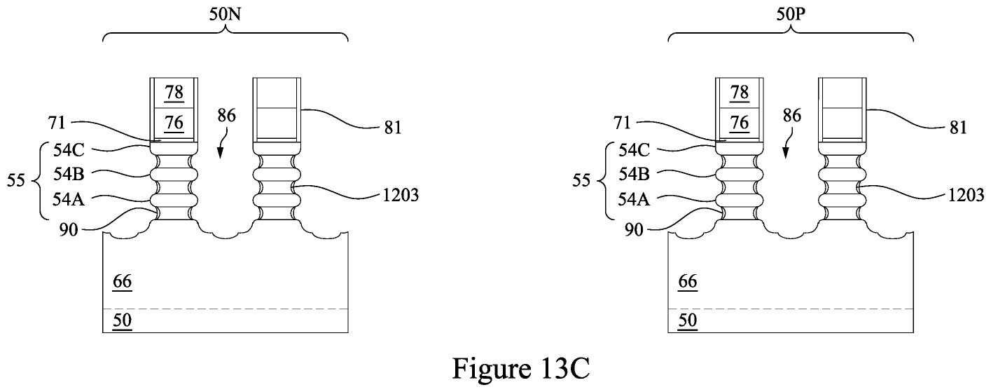

In FIGS. 13A-13C, first inner spacers 90 are formed in the interposer recesses 1205 in the n-type region 50N and in the p-type region 50P. The first inner spacers 90 may be formed by depositing an inner spacer layer (not separately illustrated) over the structures illustrated in FIGS. 12A and 12B. The first inner spacers 90 act as isolation features between subsequently formed source/drain regions and a gate structure. As will be discussed in greater detail below, source/drain regions will be formed in the first recesses 86, while the interposer 1203 in the n-type region 50N and in the p-type region 50P will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and in the p-type region 50P, the outer sidewalls of the first inner spacers 90 may extend beyond or be recessed from sidewalls of the second nanostructures 54.

Moreover, although the outer sidewalls of the first inner spacers 90 are illustrated as being straight in FIG. 13B, the outer sidewalls of the first inner spacers 90 may be concave or convex. As an example, FIG. 13C illustrates an embodiment in which sidewalls of the interposer 1203 in the n-type region 50N and in the p-type region 50P are concave, outer sidewalls of the first inner spacers 90 are concave, and the first inner spacers are recessed from sidewalls of the second nanostructures 54 in the n-type region 50N and in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 14A-14C) by subsequent etching processes, such as etching processes used to form gate structures.

In FIGS. 14A-14C, epitaxial source/drain regions 92 are formed in the first recesses 86. As illustrated in FIG. 14B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be epitaxially grown in the first recesses 86 in the n-type region 50N and may include any acceptable material appropriate for n-type nano-FETs. The epitaxial source/drain regions 92 in the p-type region 50P, e.g., the PMOS region, may be epitaxially grown in the first recesses 86 in the p-type region 50P and may include any acceptable material appropriate for p-type nano-FETs.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same NSFET to merge as illustrated by FIG. 14A. In other embodiments, adjacent epitaxial source/drain regions 92 remain separated after the epitaxy process is completed as illustrated by FIG. 14C. In the embodiments illustrated in FIGS. 14A and 14C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 14D illustrates an embodiment in which sidewalls of the interposer 1203 in the n-type region 50N and in the p-type region 50P are concave, outer sidewalls of the first inner spacers 90 are concave, and the first inner spacers 90 are recessed from sidewalls of the second nanostructures 54 in the n-type region 50N and in the p-type region 50P. As illustrated in FIG. 12D, the epitaxial source/drain regions 92 may be formed in contact with the first inner spacers 90 and may extend past sidewalls of the second nanostructures 54 in the n-type region 50N and in the p-type region 50P.

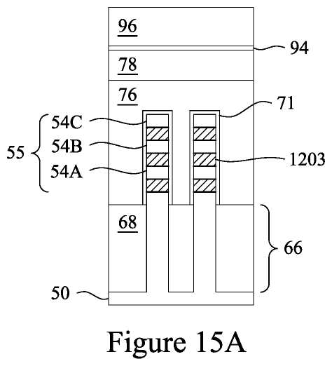

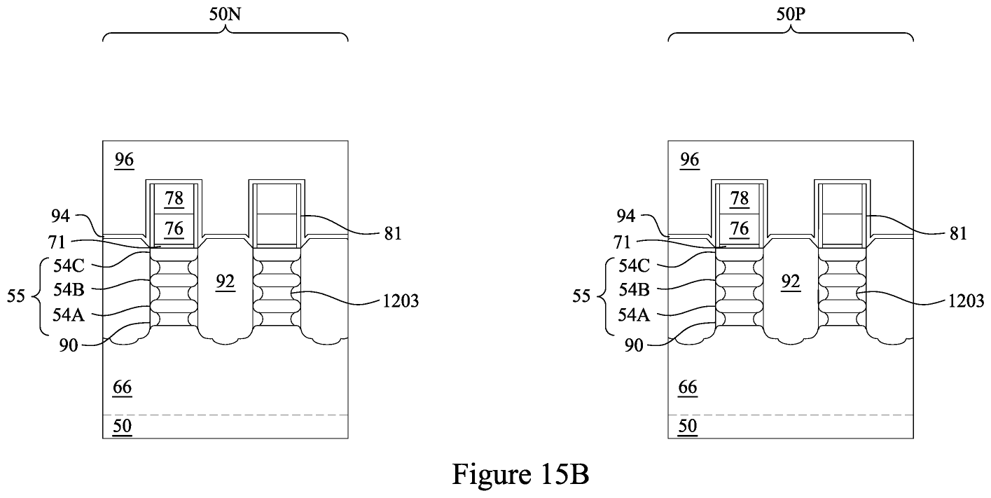

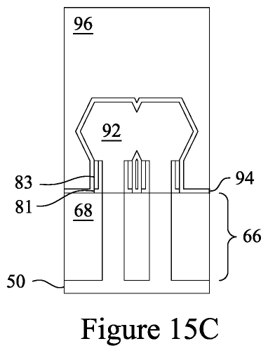

In FIGS. 15A-15C, a first interlayer dielectric (ILD) 96 is deposited over the structure illustrated in FIGS. 6A, 14B, and 14A, respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 74, and the first spacers 81. The CESL 94 may comprise a dielectric material, such as, silicon nitride, silicon oxide, silicon oxynitride, or the like, having a different etch rate than the material of the overlying first ILD 96.

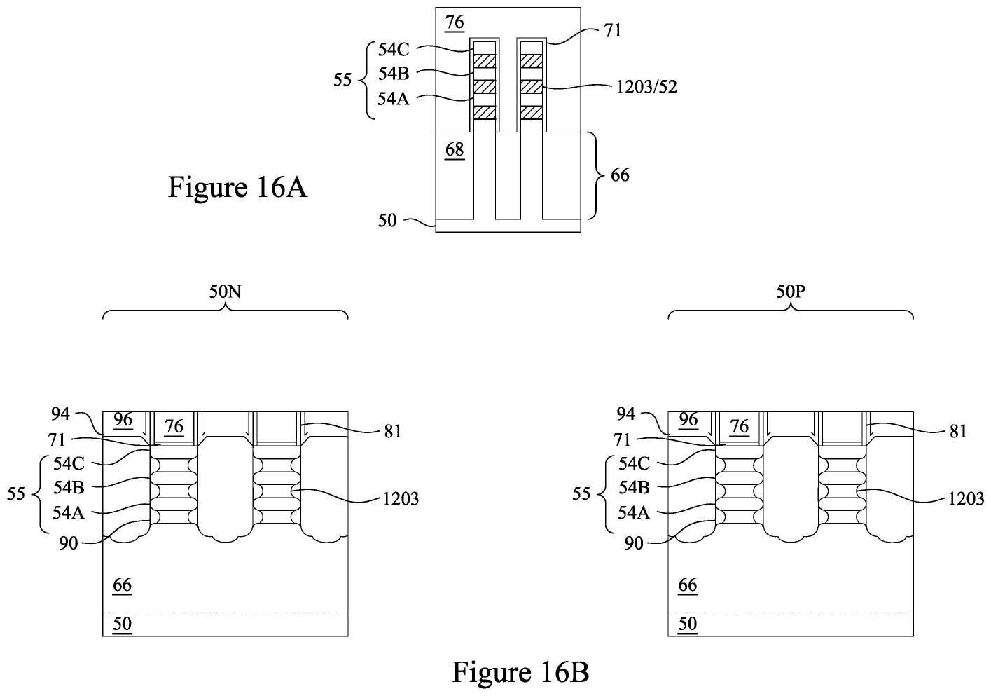

In FIGS. 16A-16C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

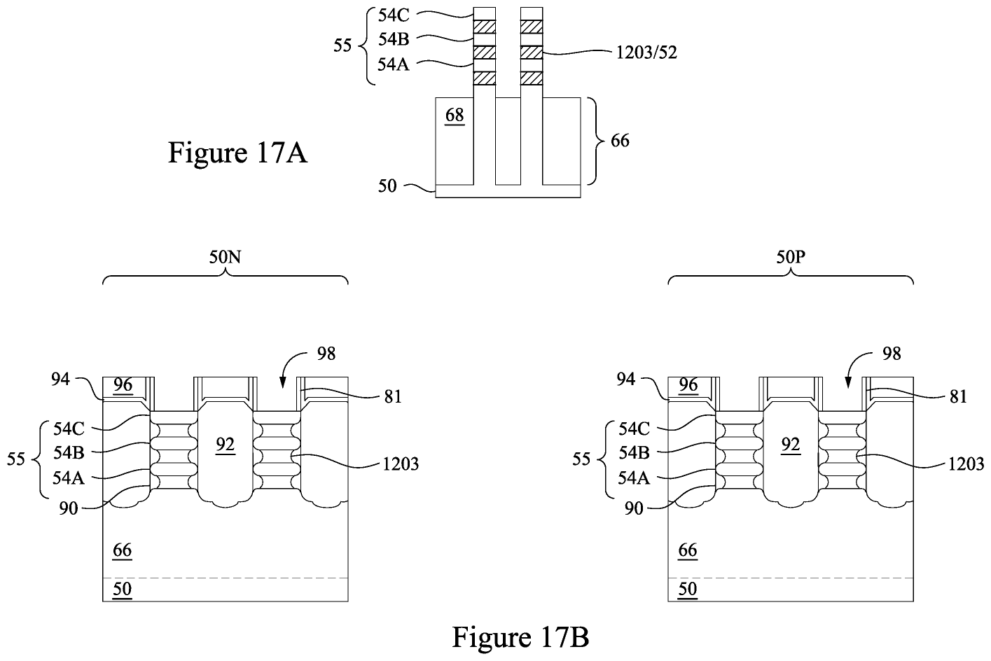

In FIGS. 17A and 17B, the dummy gates 76, and the masks 74 if present, are removed in one or more etching steps, so that second recesses 98 are formed. Portions of the dummy gate dielectrics 60 in the second recesses 98 are also be removed. In some embodiments, the dummy gates 76 and the dummy gate dielectrics 60 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 60 may be used as etch stop layers when the dummy gates 76 are etched. The dummy gate dielectrics 60 may then be removed after the removal of the dummy gates 76.

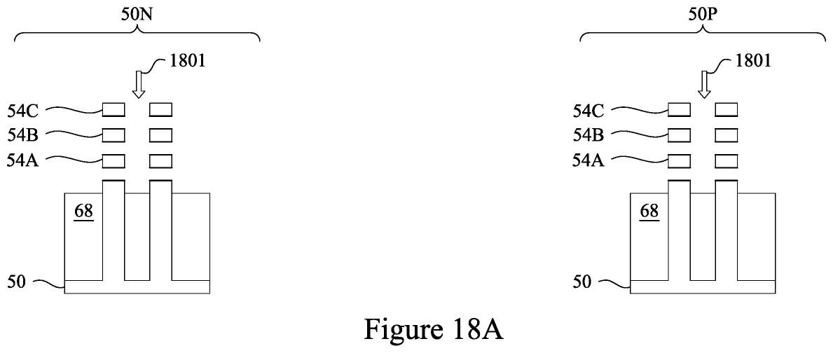

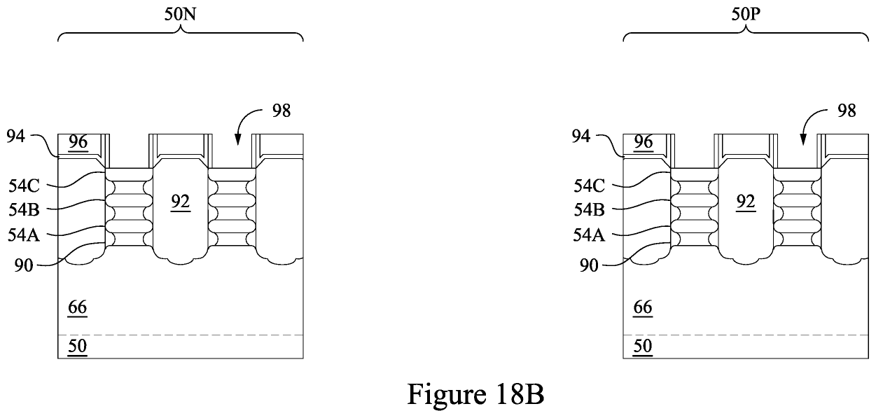

In FIGS. 18A and 18B, the interposer 1203 in the n-type region 50N and in the p-type region 50P are removed extending the second recesses 98 in accordance with some embodiments. The interposer 1203 may be removed by a third etching process 1801. The third etching process 1801 may be a cyclic dry etching process. The third etching process 1801 may utilize hydrogen fluoride (HF) gas, ammonia (NH₃) gas, the like, or a combination thereof. However, any suitable etching process or etching parameters may be utilized to remove the interposer 1203.

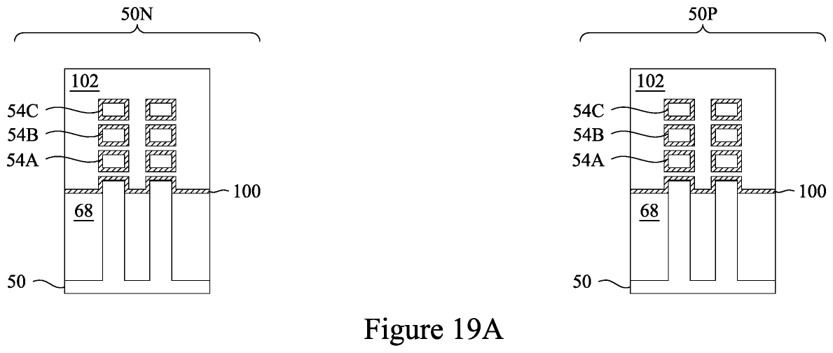

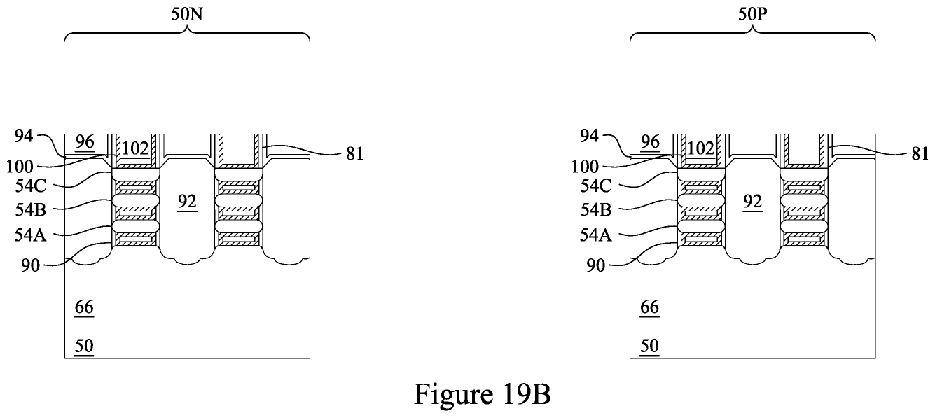

In FIGS. 19A and 19B, gate dielectric layers 100 and gate electrodes 102 are formed for replacement gates. The gate dielectric layers 100 are deposited conformally in the second recesses 98. In the n-type region 50N and in the p-type region 50P, the gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the first spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 19A and 19B, the gate electrodes 102 may comprise any number of liner layers, any number of work function tuning layers, and a fill material. Any combination of the layers which make up the gate electrodes 102 may be deposited in the n-type region 50N and in the p-type region 50P between adjacent ones of the second nanostructures 54 and between the second nanostructure 54A and the substrate 50.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

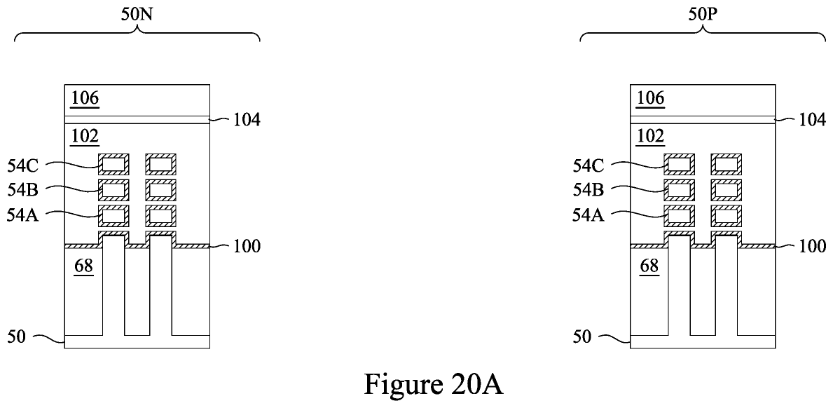

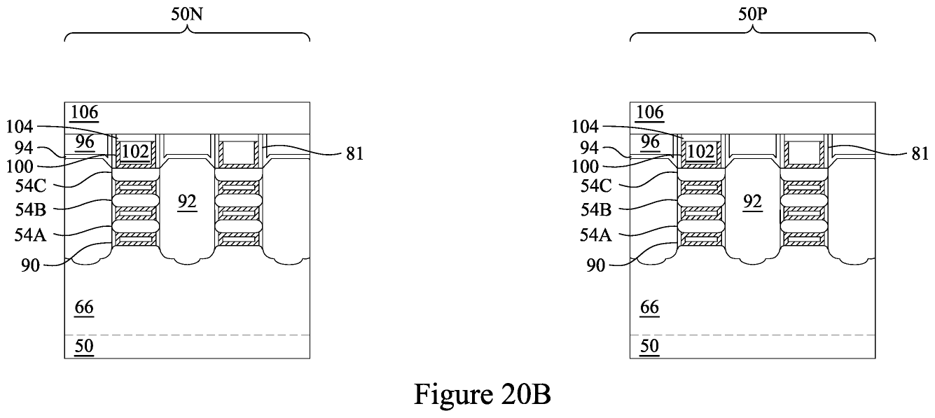

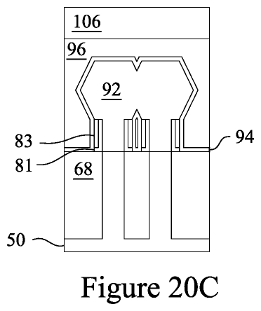

In FIGS. 20A-20C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the contacts 114, discussed below with respect to FIGS. 22A and 22B) penetrate through the gate mask 104 to contact the top surface of the recessed gate electrodes 102.

As further illustrated by FIGS. 20A-20C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

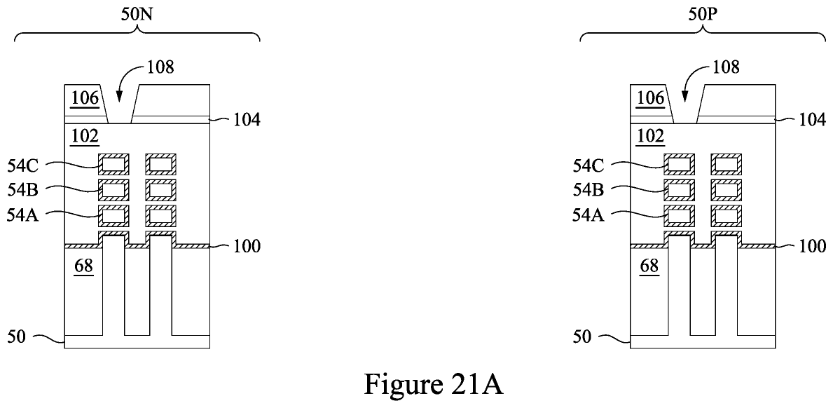

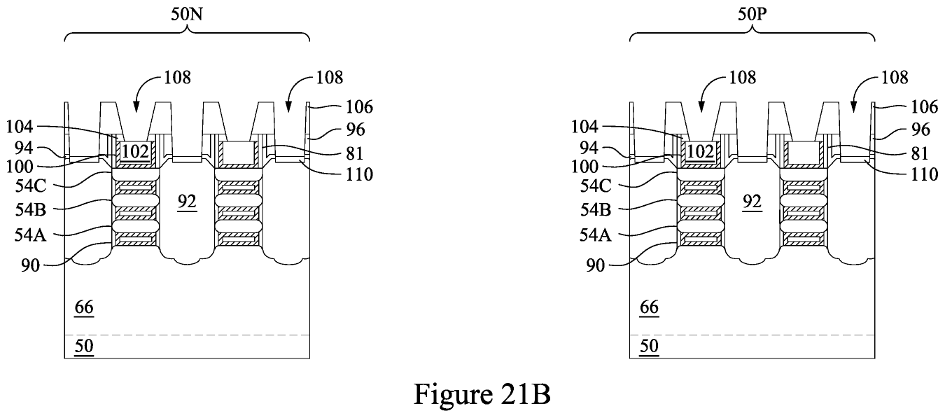

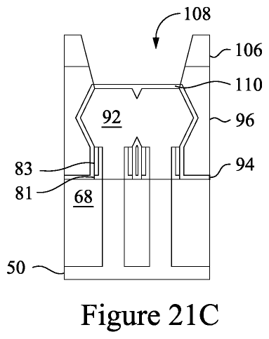

In FIGS. 21A-21C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etch; may be etched through the gate masks 104 using a second etch; and may then be etched through the CESL 94 using a third etch. A mask, such as a photoresist, may be formed and patterned over the second ILD 106 to mask portions of the second ILD 106 from the first etch and the second etch. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 21B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range of 2 nm to 10 nm.

Next, in FIGS. 22A-C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material 118, and is electrically coupled to the underlying conductive feature (e.g., gate structure 102 and/or silicide region 110 in the illustrated embodiment). The contacts 114 are electrically coupled to the gate structure 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material 118 may be copper, a copper alloy, silver, gold, tungsten, cobalt, aluminum, nickel, or the like. A planarization process, such as a CMP, may be performed to remove excess material from a surface of the second ILD 106.

The embodiments and structures discussed herein with respect to FIGS. 2 through 22C have been illustrated as occurring within both the n-type region 50N and the p-type region 50P of the nano-FETs and can be achieved by applying the processes and methods discussed with respect to FIGS. 2 through 22C in both the n-type region 50N and the p-type region 50P of the nano-FETs. However, in other embodiments, the processes and methods discussed with respect to FIGS. 2 through 22C may be applied in a similar manner as discussed with respect to FIGS. 2 through 22C to form certain structures exclusively in the n-type region 50N or exclusively in the p-type region 50P. An example of such an embodiment is illustrated in FIGS. 23A through 23C.

FIGS. 23A-C illustrate cross-sectional views of a device according to some alternative embodiments. FIG. 23A illustrates reference cross-section A-A′ illustrated in FIG. 1. FIG. 23B illustrates reference cross-section B-B′ illustrated in FIG. 1. FIG. 23C illustrates reference cross-section C-C′ illustrated in FIG. 1. In FIGS. 23A-C, like reference numerals indicate like elements. However, in FIGS. 23A-C, channel regions in the n-type region 50N and the p-type region 50P comprise a different material. For example, the second nanostructures 54, which comprise silicon, provide channel regions for n-type NSFETs in the n-type region 50N and first nanostructures 52, which comprise silicon germanium, provide channel regions for p-type NSFETs in the p-type region 50P. However, for example, the second nanostructures 54, which comprise silicon, may provide channel regions for p-type NSFETs in the p-type region 50P and first nanostructures 52, which comprise silicon germanium, may provide channel regions for n-type NSFETs in the n-type region 50N.

In accordance with some embodiments where the interposer 1203 is formed exclusively in the n-type region 50N, the channel region in the n-type region 50N is formed from silicon (as illustrated in FIGS. 23A through 23C) and the channel region in the p-type region 50P may be formed from either silicon germanium (as illustrated in FIGS. 23A through 23C) or from silicon. In this embodiment, the channel region in the n-type region 50N may be formed through a series of processes similar to those discussed with respect to FIGS. 2 through 22C. In this embodiment, a photoresist or other masks (not separately illustrated) may be applied over the p-type region 50P during the first etching process 1001 to remove the first nanostructures 52 from the n-type region 50N while leaving the first nanostructures 52 intact in the p-type region 50P. In this embodiment, during the first deposition process 1101, a photoresist or other masks (not separately illustrated) is present over the p-type region 50P so that the p-type region 50P is isolated and the interposer material 1103 is exclusively deposited in the n-type region 50N of the nano-FETs. This isolation method of applying a photoresist or other masks (not separately illustrated) to isolate one region from the other during the first deposition process 1101 may also be employed during subsequent treatment steps. The interposer material 1103 in the n-type region 50N may then be subjected to the post-deposition curing 1105, the post-deposition treatment 1107, and the post-deposition anneal process 1109. With a photoresist or other masks (not separately illustrated) present over the p-type region 50P the second etching process 1201 may be performed on the interposer material 1103 exclusively in the n-type region 50N forming the interposer 1203 exclusively in the n-type region 50N. The channel region in the n-type region 50N may then proceed to be formed following similar methods as discussed with respect to FIGS. 13A through 22C.

In the above embodiment, the channel region in the p-type region 50P may be formed through a series of processes similar to those discussed with respect to FIGS. 2 through 22C. In this embodiment, the channel region in the p-type region 50P follows the processes discussed with respect to FIGS. 2 through 9B, a photoresist or other masks (not separately illustrated) is then formed over the n-type region 50N. Portions of sidewalls of sacrificial layers of the multi-layer stack 64 (layers that do not form the channel region in the p-type region 50P) in the p-type region 50P exposed by the first recesses 86 in the p-type region 50P are etched to form sidewall recesses in the p-type region 50P. Although sidewall recesses in the p-type region 50P are illustrated as being straight in FIG. 23B in the p-type region 50P, the sidewalls may be concave or convex. In this embodiment, structures in the p-type region 50P may then be formed in a similar manner as discussed with respect to FIGS. 13A through 17B. Following the formation of the structures in the p-type region 50P as discussed with to FIGS. 13A through 17B sacrificial layers of the multi-layer stack 64 in the p-type region 50P may be removed by having a photoresist or other masks (not separately illustrated) over the n-type region 50N and performing an isotropic etching process such as wet etching or the like using etchants which are selective to the materials of the sacrificial layers of the multi-layer stack 64 to remove the sacrificial layers of the multi-layer stack 64 in the p-type region 50P. The channel region in the p-type region 50P may then be formed in a similar manner as discussed with respect to FIGS. 19A through 22C utilizing suitable processes for the material utilized for the channel region in the p-type region 50P.

In accordance with some embodiments where the interposer 1203 is formed exclusively in the p-type region 50P, the channel region in the p-type region 50P is formed from silicon and the channel region in the n-type region 50N may be formed from either silicon germanium or from silicon. In this embodiment, the channel region in the p-type region 50P may be formed through a series of processes similar to those discussed with respect to FIGS. 2 through 22C. In this embodiment, a photoresist or other masks (not separately illustrated) may be applied over the n-type region 50N during the first etching process 1001 to remove the first nanostructures 52 from the p-type region 50P while leaving the first nanostructures 52 intact in the n-type region 50N. In this embodiment, during the first deposition process 1101, a photoresist or other masks (not separately illustrated) is present over the n-type region 50N so that the n-type region 50N is isolated and the interposer material 1103 is exclusively deposited in the p-type region 50P of the nano-FETs. This isolation method of applying a photoresist or other masks (not separately illustrated) to isolate one region from the other during the first deposition process 1101 may also be employed during subsequent treatment steps. The interposer material 1103 in the p-type region 50P may then be subjected to the post-deposition curing 1105, the post-deposition treatment 1107, and the post-deposition anneal process 1109. With a photoresist or other masks (not separately illustrated) present over the n-type region 50N the second etching process 1201 may be performed on the interposer material 1103 exclusively in the p-type region 50P forming the interposer 1203 exclusively in the p-type region 50P. The channel region in the p-type region 50P may then proceed to be formed following similar methods as discussed with respect to FIGS. 13A through 22C.

In the above embodiment, the channel region in the n-type region 50N may be formed through a series of processes similar to those discussed with respect to FIGS. 2 through 22C. In this embodiment, the channel region in the n-type region 50N follows the processes discussed with respect to FIGS. 2 through 9B, a photoresist or other masks (not separately illustrated) is then formed over the p-type region 50P. Portions of sidewalls of sacrificial layers of the multi-layer stack 64 (layers that do not form the channel region in the n-type region 50N) in the n-type region 50N exposed by the first recesses 86 in the n-type region 50N are etched to form sidewall recesses in the n-type region 50N. The sidewalls may be straight, concave, or convex. In this embodiment, structures in the n-type region 50N may then be formed in a similar manner as discussed with respect to FIGS. 13A through 17B. Following the formation of the structures in the n-type region 50N as discussed with to FIGS. 13A through 17B sacrificial layers of the multi-layer stack 64 in the n-type region 50N may be removed by having a photoresist or other masks (not separately illustrated) over the p-type region 50P and performing an isotropic etching process such as wet etching or the like using etchants which are selective to the materials of the sacrificial layers of the multi-layer stack 64 to remove the sacrificial layers of the multi-layer stack 64 in the n-type region 50N. The channel region in the n-type region 50N may then be formed in a similar manner as discussed with respect to FIGS. 19A through 22C utilizing suitable processes for the material utilized for the channel region in the n-type region 50N.

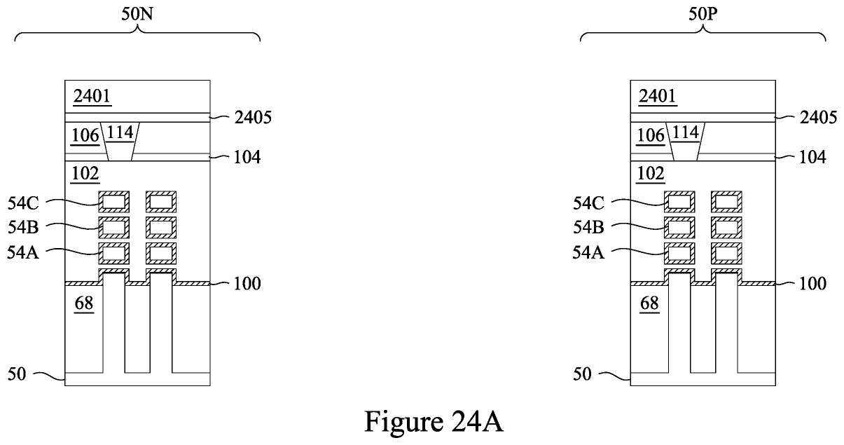

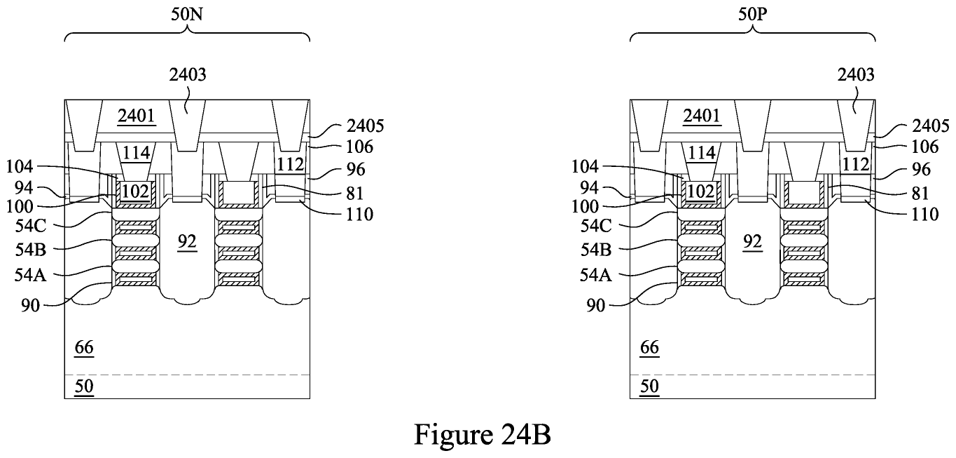

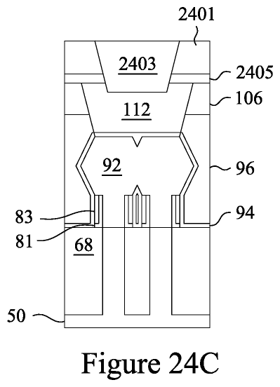

FIGS. 24A-24C illustrate an additional embodiment wherein a third ILD 2401 is formed over the second ILD 106 of the structures of either FIGS. 22A-22C or FIGS. 23A-23C and an outer contact plug 2403 is formed through the third ILD 2401. In some embodiments a second mask layer 2405 is utilized for the formation of the outer contact plug 2403 through the third ILD 2401.

In accordance with some embodiments, following the deposition of the second ILD 106 a second mask layer 2405 is formed over the second ILD 106. The second mask layer 2405 may be formed by a deposition process such as chemical vapor deposition, physical vapor deposition, atomic layer deposition, combinations of these, or the like. The second mask layer 2405 may include, for example, silicon nitride, silicon oxide, silicon carbide, silicon oxynitride, combinations of these, or the like. Following the formation of the second mask layer 2405, the third ILD 2401 may be formed over the second mask layer 2405. In some embodiments, the third ILD 2401 is a flowable film formed by FCVD. In some embodiments, the third ILD 2401 is formed of a dielectric material such as PSG, BSG, BPSG, USG, or the like, and may be deposited by any suitable method, such as CVD, PECVD, or the like.

In FIGS. 24A-24C, the third ILD 2401 and the second mask layer 2405 are etched to form fourth recesses (not separately illustrated) exposing surfaces of the contacts 112. The fourth recesses may be formed by etching using an anisotropic etching process, such as RIE, NBE, or the like. In some embodiments, the etching may over-etch, and therefore, the fourth recesses may extend into the contacts 112.

Following the formation of the fourth recesses, the outer contact plug 2403 is formed in the fourth recesses. The outer contact plug 2403 may comprise one or more layers, such as barrier layers, diffusion layers, and fill materials. For example, in some embodiments, the outer contact plug 2403 includes a barrier layer (not separately illustrated) and a conductive material (not separately illustrated), and is electrically coupled to the underlying conductive feature (e.g., the contacts 112 in the illustrated embodiment). The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the third ILD 2401. Following the planarization process, the outer contact plug 2403 and the third ILD 2401 may share a planar surface.

Embodiments may achieve advantages. For example, where the first nanostructures 52 are formed of SiGe and the second nanostructures 54 are formed of Si by removing the first nanostructure 52 in either or both the n-type region 50N and/or the p-type region 50P prior to forming the first inner spacers 90 the risk of nanosheet intermixing resulting from subsequent thermal processes is mitigated. Further, by utilizing the first deposition process 1101, the interposer 1203 is able to be formed due to the lateral filling capabilities of the c-FCVD processes and the interposer 1203 is able to be formed in place of the first nanostructure 52 to be utilized during subsequent processing with reduced risk of nanosheet intermixing that may be caused by loop thermal processing during the subsequent processing.

In accordance with some embodiments of the present disclosure a method of manufacturing a semiconductor device includes: forming first nanostructures from a first material over a substrate; forming second nanostructures from a second material different from the first material over the substrate, wherein the first nanostructures and the second nanostructures alternate vertically above the substrate; removing the first nanostructures; after the removing the first nanostructures forming an interposer in between the second nanostructures; after the forming the interposer forming a first source/drain region over the substrate and in direct physical contact with the second nanostructures; and removing the interposer exposing surfaces of each of the second nanostructures. In an embodiment the forming the interposer includes depositing the interposer at least in part by contour-flowable chemical vapor deposition (c-FCVD) process, the interposer coating exposed surfaces of the substrate, sidewalls of each of the second nanostructures and laterally filling gaps between each of the second nanostructures and between a bottommost second nanostructure of the second nanostructures and the substrate. In an embodiment the c-FCVD process utilizes trisilylamine as a precursor. In an embodiment further including introducing ozone to the interposer during an ultraviolet curing process densifying a portion of the interposer. In an embodiment further including performing a sulfuric acid-hydrogen peroxide mixture process on the interposer. In an embodiment further including performing a furnace anneal process on the interposer, the furnace anneal process utilizing steam. In an embodiment wherein the interposer comprises silicon oxide, silicon nitride, or silicon oxynitride.

In accordance with some embodiments of the present disclosure a method of manufacturing a semiconductor device includes: forming a multi-layer stack over a substrate, the multi-layer stack including: a first semiconductor material; and a second semiconductor material different from the first semiconductor material, wherein the first semiconductor material and the second semiconductor material are in alternating layers within the multi-layer stack; forming a first set of nanostructures from the first semiconductor material; forming a second set of nanostructures from the second semiconductor material; removing the first set of nano structures; forming an interposer in between the second set of nanostructures where the first set of nanostructures have been removed; and replacing the interposer with a gate electrode. In an embodiment the first semiconductor material is formed of silicon germanium and the second semiconductor material is formed of silicon. In an embodiment the first set of nanostructures are removed utilizing a dry etching process. In an embodiment further including forming spacers adjacent to the interposer and in between the second set of nanostructures where the first set of nanostructures have been removed. In an embodiment further including depositing an oxide film over exposed surfaces of the second set of nanostructures after the removing of the first set of nanostructures, wherein the oxide film is deposited prior to the forming the interposer. In an embodiment after the depositing the oxide film the forming the interposer includes utilizing a contour-flowable chemical vapor deposition (c-FCVD) process to deposit an interposer material over exposed surfaces of the substrate and surrounding each of the second set of nanostructures, wherein the interposer material is seam-free in between each of the second set of nanostructures. In an embodiment the forming the interposer further includes etching the interposer material to remove portions of the interposer material over the substrate not directly underneath the second set of nanostructures, on sidewalls of the second set of nanostructures and in between each of the second set of nanostructures, wherein the etching is a cyclic dry etching process.

In accordance with some embodiments of the present disclosure a method of manufacturing a semiconductor device includes: forming a first stack of nanostructures over a semiconductor fin, the first stack of nanostructures including: first nanostructures formed from silicon germanium; and second nanostructures formed from silicon, wherein the first nanostructures and the second nanostructures alternate within the first stack of nanostructures; performing a first etching process to remove the first nanostructures; forming an interposer in between the second nanostructures; after the forming the interposer growing a first source/drain region over the semiconductor fin and adjacent to the second nanostructures; removing the interposer; after the removing the interposer forming gate dielectric layers surrounding each of the nanostructures of the second nanostructures; and forming a continuous gate electrode surrounding the gate dielectric layers. In an embodiment further including forming spacers in between the second nanostructures isolating the interposer from the first source/drain region. In an embodiment the spacers have a concave profile. In an embodiment further including performing a furnace anneal process on the interposer, the furnace anneal process utilizing nitrogen gas and operating at a maximum temperature of 1,000° C. In an embodiment the forming the interposer comprises utilizing at least in part a contour-flowable chemical vapor deposition (c-FCVD) process. In an embodiment the interposer includes silicon oxide, silicon nitride, or silicon oxynitride.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
forming first nanostructures from a first material over a substrate;
forming second nanostructures from a second material different from the first material over the substrate, wherein the first nanostructures and the second nanostructures alternate vertically above the substrate;
removing the first nanostructures;
after the removing the first nanostructures forming an interposer in between the second nanostructures;
after the forming the interposer forming a first source/drain region over the substrate and in direct physical contact with the second nanostructures; and
removing the interposer exposing surfaces of each of the second nanostructures.

2. The method of claim 1, wherein the forming the interposer comprises depositing the interposer at least in part by a contour-flowable chemical vapor deposition (c-FCVD) process, the interposer coating exposed surfaces of the substrate, sidewalls of each of the second nanostructures and laterally filling gaps between each of the second nanostructures and between a bottommost second nanostructure of the second nanostructures and the substrate.

3. The method of claim 2, wherein the c-FCVD process utilizes trisilylamine as a precursor.

4. The method of claim 3, further comprising introducing ozone to the interposer during an ultraviolet curing process densifying a portion of the interposer.

5. The method of claim 4, further comprising performing a sulfuric acid-hydrogen peroxide mixture process on the interposer.

6. The method of claim 5, further comprising performing a furnace anneal process on the interposer, the furnace anneal process utilizing steam.

7. The method of claim 6, wherein the interposer comprises silicon oxide, silicon nitride, or silicon oxynitride.

8. A method of manufacturing a semiconductor device, the method comprising:
forming a multi-layer stack over a substrate, the multi-layer stack comprising:
a first semiconductor material; and
a second semiconductor material different from the first semiconductor material, wherein the first semiconductor material and the second semiconductor material are in alternating layers within the multi-layer stack;
forming a first set of nanostructures from the first semiconductor material;
forming a second set of nanostructures from the second semiconductor material;
removing the first set of nanostructures;
forming an interposer in between the second set of nanostructures where the first set of nanostructures have been removed; and
replacing the interposer with a gate electrode.

9. The method of claim 8, wherein the first semiconductor material is formed of silicon germanium and the second semiconductor material is formed of silicon.

10. The method of claim 9, wherein the first set of nanostructures are removed utilizing a dry etching process.

11. The method of claim 8, further comprising forming spacers adjacent to the interposer and in between the second set of nanostructures where the first set of nanostructures have been removed.

12. The method of claim 8, further comprising depositing an oxide film over exposed surfaces of the second set of nanostructures after the removing of the first set of nanostructures, wherein the oxide film is deposited prior to the forming the interposer.

13. The method of claim 12, wherein after the depositing the oxide film the forming the interposer comprises utilizing a contour-flowable chemical vapor deposition (c-FCVD) process to deposit an interposer material over exposed surfaces of the substrate and surrounding each of the second set of nano structures, wherein the interposer material is seam-free in between each of the second set of nano structures.

14. The method of claim 13, wherein the forming the interposer further comprises etching the interposer material to remove portions of the interposer material over the substrate not directly underneath the second set of nanostructures, on sidewalls of the second set of nanostructures and in between each of the second set of nanostructures, wherein the etching is a cyclic dry etching process.

15. A method of manufacturing a semiconductor device, the method comprising:
forming a first stack of nanostructures over a semiconductor fin, the first stack of nanostructures comprising:
first nanostructures formed from silicon germanium; and
second nanostructures formed from silicon, wherein the first nanostructures and the second nanostructures alternate within the first stack of nanostructures;
performing a first etching process to remove the first nanostructures;
forming an interposer in between the second nanostructures;
after the forming the interposer growing a first source/drain region over the semiconductor fin and adjacent to the second nanostructures;
removing the interposer;
after the removing the interposer forming gate dielectric layers surrounding each of the nanostructures of the second nanostructures; and
forming a continuous gate electrode surrounding the gate dielectric layers.

16. The method of claim 15, further comprising forming spacers in between the second nanostructures isolating the interposer from the first source/drain region.

17. The method of claim 16, wherein the spacers have a concave profile.

18. The method of claim 15, further comprising performing a furnace anneal process on the interposer, the furnace anneal process utilizing nitrogen gas and operating at a maximum temperature of 1,000° C.

19. The method of claim 15, wherein the forming the interposer comprises utilizing at least in part a contour-flowable chemical vapor deposition (c-FCVD) process.

20. The method of claim 15, wherein the interposer comprises silicon oxide, silicon nitride, or silicon oxynitride.
